(19) United States
(12) Patent Application Publication
(10) Pub. No.: US 2025/0309616 A1
(43) Pub. Date: Oct. 2, 2025

(54) Broad-area diode laser comprising integrated p-n tunnel junction

(71) Applicant: Ferdinand-Braun-Institut gGmbH Leibniz-Institut Fuer Hoechstfre Quenztechnik, Berlin (DE)

(72) Inventors: Paul Crump, Berlin (DE); Hans Wenzel, Berlin (DE); Mohamed Elattar, Berlin (DE); Andre Maassdorf, Berlin (DE); Dominik Martin, Berlin (DE); Olaf Brox, Berlin (DE)

(21) Appl. No.: 18/864,703

(22) PCT Filed: May 11, 2023
(86) PCT No.: PCT/EP2023/062685

§ 371 Date: Nov. 11, 2024

(30) Foreign Application Priority Data
May 12, 2022 (DE) 10 2022 111 977.7

(51) Int. Cl. H01S 5/20; H01S 5/22; H01S 5/30; H01S 5/323

(52) U.S. Cl. CPC H01S 5/2036; H01S 5/2205; H01S 5/3054; H01S 5/32316

(57) ABSTRACT

The present invention relates to a broad-area diode laser (BAL) comprising an integrated p-n tunnel junction. The present invention in particular relates to a high-performance broad-area diode laser in which, in order to improve the beam quality and to reduce the thermal resistance, a p-n tunnel junction, biased in the reverse direction, is integrated in the layer system of the diode laser.

A laser diode according to the invention comprises an active layer (20) formed between an n-doped semiconductor material (10, 12, 14) and a p-doped semiconductor material (30, 32, 34), the active layer (20) forming, along a longitudinal axis, an active zone for generating electromagnetic radiation; wherein at least one n-doped intermediate layer (50, 54) is arranged between an overlying p-side metal contact (52) and the p-doped semiconductor material (30, 32, 34), and, in the at least one n-doped intermediate layer (50, 54) in the region above the active zone, a p-n tunnel junction (40) being formed which is directly adjacent to the p-doped semiconductor material (30, 32, 34).

The present invention relates to a broad-area diode laser (BAL) comprising an integrated p-n tunnel junction. The present invention in particular relates to a high-performance broad-area diode laser in which, in order to improve the beam quality and to reduce the thermal resistance, a p-n tunnel junction, biased in the reverse direction, is integrated in the layer system of the diode laser.

### PRIOR ART

Broad-area diode lasers can have particularly high efficiency and brilliance. Using these emitters, power outputs of >15 W can be reliably obtained. BALs are the most efficient light source for near-infrared radiation (NIR), and therefore they are commonplace as a pumping source for solid-state lasers and fiber lasers. They are also the key element of fiber-coupled laser systems, which are configured to provide beams having a high radiation density for material processing with high conversion efficiencies. In order to increase the power output of these systems and reduce their costs, it is important to improve the beam quality of the slow axis in particular, since this allows a greater number of emitters to be coupled in fibers having a low numerical aperture (NA).

At high optical power outputs and the associated operating currents, however, there is generally considerable degradation in the beam quality, and this in particular has a negative effect on fiber coupling. It was possible to demonstrate that thermal lensing (rather than carrier- or gain-induced guiding) in the slow axis is the predominant cause of beam quality degradation at an increased operating current (Bai, J. G. et al., Mitigation of Thermal Lensing Effect as a Brightness Limitation of High-Power Broad Area Diode Lasers, Proc. SPIE 7953, 79531F (2011) & Crump, P. et al., Experimental Studies Into the Beam Parameter Product of GaAs High-Power Diode Lasers, IEEE J. Sel. Top. Quantum Electron., vol. 28, no. 1 (2022)). It is thus crucial for the beam quality degradation at high power outputs to configure a lateral temperature gradient on the basis of a temperature increase in the central region below the laser stripe, which results in a local increase in the refractive index, and thus in additional lateral wave guidance and consequently in a greater divergence angle.

In particular, earlier studies of GaAs-based broad-area diode lasers (e.g. Rieprich, J. et al., Thermal boundary resistance between GaAs and p-side metal as limit to high power diode lasers, IEEE High Power Diode Lasers and Systems Conf. (Coventry, UK), pp. 35-36 (2019)) have demonstrated that a considerable thermal barrier forms at the boundary between the highly p-doped GaAs contact layer and the metal contact deposited thereabove. The heat dissipation reduced by this barrier intensifies the effect of the resulting thermal lensing, which results in a lower beam quality and increased thermal resistance. A thermal barrier of this kind could not be observed at the other semiconductor-metal boundary within the component, i.e. between n-doped GaAs and metal, however.

### DISCLOSURE OF THE INVENTION

The object of the present invention is therefore to provide a broad-area diode laser in which the arising thermal barrier between a highly p-doped contact layer and the metal contact deposited thereabove is to be reduced or entirely prevented in order to improve the beam quality and to reduce the thermal resistance.

These objects are achieved according to the invention by the features of independent claim 1. Expedient configurations of the invention are found in the dependent claims.

The present invention relates to a laser diode comprising an active layer formed between an n-doped semiconductor material and a p-doped semiconductor material, the active layer forming, along a longitudinal axis, an active zone for generating electromagnetic radiation; wherein at least one n-doped intermediate layer is arranged between an overlying p-side metal contact and the p-doped semiconductor material, and, in the at least one n-doped intermediate layer in the region above the active zone, a p-n tunnel junction being formed which is directly adjacent to the p-doped semiconductor material. The at least one n-doped intermediate layer preferably comprises a p-side n-contact layer. The p-side metal contact can be arranged on the p-side n-contact layer.

Here, the n-doped semiconductor material typically comprises an n-doped substrate (referred to as an n-substrate), an n-side n-cover layer arranged on the n-substrate, and an n-waveguide layer arranged on the n-side n-cover layer. The p-doped semiconductor material typically comprises a p-waveguide layer and a p-cover layer arranged on the p-waveguide layer. In the prior art, a p-contact layer is usually arranged on the p-cover layer. The active layer, which is configured for light generation, is located between the two differently doped semiconductor materials. In this case, the active zone is the portion of the active layer in which light generation actually takes place during operation of the laser diode by means of carrier injection. The longitudinal axis points in the longitudinal direction and preferably corresponds to the resonator axis of the laser.

The carriers are then usually fed over the n-substrate on the n-side and over an overlying metal contact on the p-side, with this p-side metal contact then forming a semiconductor-metal boundary with an underlying p-contact layer. As already described above, this boundary constitutes a considerable thermal barrier. Since, in an n-side semiconductor-metal boundary, a thermal barrier of this kind could not be observed, according to the invention at least one n-doped intermediate layer is arranged between the overlying p-side metal contact and the p-doped semiconductor material located thereunder. In addition, to further make the carrier injection possible, in the at least one n-doped intermediate layer in the region above the active zone, a p-n tunnel junction is formed which is directly adjacent to the p-doped semiconductor material. Therefore, a boundary, which is considered to be preferable, can also be produced on the p-side between an n-semiconductor material and a metal, i.e. without forming a considerable thermal barrier. The p-n tunnel junction preferably has a total thickness of less than 100 nm.

The present invention is based on the knowledge that a semiconductor-metal boundary comprising an n-doped semiconductor on both sides of the BAL is particularly advantageous. In order to achieve this, the p-side contact layer of the BAL can be formed to be n-doped rather than p-doped. However, this results in a p-n junction biased in the reverse direction, which acts as a power cut-off. To avoid this, a reverse-biased p-n tunnel junction, or tunnel junction (TJ) for short, is formed at this p-n boundary, which for example consists of very highly doped semiconductor layers and allows carriers to tunnel between a corresponding p-side n-contact layer and the other p-side semiconductor layers. In a design of this kind, it is crucial that the tunnel junction has a very low switch-on voltage and a very low intermediate resistance, meaning that the conversion efficiency of the BAL is not impaired. The BAL according to the invention is also referred to as a TJ-BAL.

In addition to reducing or avoiding the thermal barrier that otherwise forms at the p-side semiconductor-metal boundary, this approach provides yet more advantages. The high electrical conductivity of the highly doped n-contact and TJ layers can result in a very low intermediate resistance between the active zone and the epi-side contact, in particular in vertical structures having thin p-side waveguide and cover layers, such as in the extreme triple asymmetric structure (ETAS) design. The low intermediate resistance results in a higher conversion efficiency, in particular at higher current intensities (Crump, P. et al., Efficient High-Power Laser Diodes, IEEE J. Sel. Top. Quantum Electron., vol. 19, no. 4 (2013)). Furthermore, the planar TJ layers are so highly doped that they have a tendency toward equipotentiality, which means that differences in voltage that arise between different regions of the laser chip cannot be maintained and immediately equalize. The low epi-side resistance and the presence of equipotentiality have the advantage that they reduce spatial hole burning and suppress higher-order lateral modes, as a result of which the beam quality, the power output, and the conversion efficiency are additionally further improved (Zeghuzi, A. et al., Traveling wave analysis of non-thermal far-field blooming in high-power broad-area lasers, IEEE J. Quantum Electron., vol. 55, no. 2 (2019) & Zeghuzi, A. et al., Influence of nonlinear effects on the characteristics of pulsed high-power broad-area distributed Bragg reflector lasers, Opt. Quant. Electron., vol. 50, no. 88 (2018)).

Another advantage of the very low specific resistance of highly n-doped p-side semiconductor layers and the equipotentiality is that the thickness of the p-side n-contact layer, which grows over the p-n tunnel junction, can be considerably increased without the electrical resistance being substantially degraded. As a result, in structures having a thin p-side, the active zone can be protected against process-related and design-related mechanical stresses, which can impair the polarization purity, the power output, and the service life of the component and result in undesired wave guidance, which in turn reduces the beam quality.

The p-n tunnel junction preferably comprises a p+tunnel layer arranged on the p-doped semiconductor material and an n+tunnel layer arranged thereon. Owing to the high doping of the two tunnel layers of the p-n tunnel junction, the carriers can tunnel through the reverse-biased p-n junction formed at the boundary between the at least one p-side n-doped intermediate layer and the p-doped semiconductor material, such that the electrical resistance still remains low during the carrier injection. The doping concentration of the n-doped and p-doped layers of the p-n tunnel junction is preferably N_{D,A}≥10¹⁹ cm⁻³ (routine doping concentration of the environment is approximately up to 10¹⁸ cm⁻³).

The p-n tunnel junction is preferably arranged on a p-doped sub-contact layer (p-sub-contact layer) of the p-doped semiconductor material. The p-sub-contact layer substantially corresponds to the p-contact layer in the prior art. According to the invention, however, a metal contact is not arranged on the p-sub-contact layer, but is instead separated from the p-sub-contact layer by the at least one n-doped intermediate layer. The p-sub-contact layer can differ from the p-cover layer arranged thereunder either on account of the semiconductor material or its composition, or on account of a discontinuity in the progression of the refractive index/the refractive index gradient at the layer boundary.

The p-n tunnel junction is preferably arranged on a p-doped cover layer of the p-doped semiconductor material. In this case, a p-sub-contact layer is not arranged between the p-doped cover layer and the p-n tunnel junction. An n-doped cover layer is preferably arranged on the p-n tunnel junction. This means that the p-side cover layer comprises a p-doped and an n-doped region, between which the p-n tunnel junction is arranged. Since the optical modes guided in the waveguide layer also extend as far as the cover layers, this means that the optical modes can extend beyond the p-n tunnel junction on the p-side into the p-side n-doped cover layer. A contact layer that potentially adjoins this does not play a substantial role in the wave guidance.

A stripe width of the diode laser is preferably specified over a lateral width W of the p-n tunnel junction. By means of the reverse p-n junction that arises everywhere outside the p-n tunnel junction, the injection area can be defined by the geometric definition of the p-n tunnel junction. Therefore, the current path can be specified by the size and shape of the p-n tunnel junction.

As an alternative, the p-n tunnel junction can be formed as a layer and a stripe width of the diode laser is specified over a lateral width W of an opening in an n-current shield introduced into the p-doped semiconductor material. In this case, the p-n tunnel junction negates the effect of the reverse p-n junction over a wide area, and the structuring of individual stripes needs to take place in another way. The proposed n-current shields are well known from the prior art for limiting the flow of current. The current path can thus be specified by the size and shape of the opening in the n-current shield (shield opening) in a completely identical manner to the above-described embodiment. The p-n tunnel junction preferably has a total thickness of less than 100 nm, the doping concentration of the n-current shield preferably being N_{D}≥10¹⁸ cm⁻³.

If the p-n tunnel junction is formed as a layer, the stripe width of the diode laser can instead be specified over an n-current shield and over a lateral width W of a region between two adjacent deep implantation areas (e.g. by means of ion implantation). By means of the deep implantation, the resistance in the treated areas can be increased so much that there is effectively only a flow of current over the non-deep implanted regions. Here, the deep implantation preferably reaches from the metal contact into the p-cover layer. The intermediate resistance of the deep implantation area is preferably at least twice as high as that of the surrounding area.

The semiconductor material is preferably based on GaAs. For example, an n-substrate GaAs can comprise an n-side n-cover layer AlGaAs, an n-waveguide layer AlGaAs, a p-waveguide layer AlGaAs, and a p-cover layer AlGaAs. A p-sub-contact layer can comprise GaAs. A p-n tunnel junction can comprise p⁺ GaAs as the p⁺ tunnel layer and n⁺ GaAs as the n⁺ tunnel layer. An n-contact layer can comprise GaAs. A p-side n-cover layer can comprise AlGaAs.

The minimum distance between the active layer and the p-n tunnel junction is preferably less than 1.3 μm, preferably less than 1 μm, and more preferably less than 0.5 μm. The advantage of the smallest possible distance between the active layer and the p-n tunnel junction is the reduction in the intermediate resistance and the spatial hole burning, as a result of which the laser properties (e.g. beam quality, power, efficiency) are improved.

Different lateral structuring techniques can be implemented in the TJ-BALs according to the invention in order to limit the current to the center of the component (i.e. below the laser stripe or above the active zone). The resulting current limitation limits the losses at the stripe edges and limits the disadvantageous effects of the lateral current spreading and the lateral carrier accumulation (LCA) on the beam quality. In these TJ-BALs, the current limitation is more significant than in standard BALs, since the current spreading in an n-contact layer is substantially greater than in a p-contact layer owing to the greater mobility of electrons compared with holes.

The residual layer thickness dᵣₑₛ between the active zone and a current shield is preferably less than 1 μm. Disadvantageous current spreading can be reduced by means of the lowest possible residual layer thickness dᵣₑₛ. In this case, the residual layer thickness dᵣₑₛ generally represents the minimum distance between the active layer and a structure that is closest to the active layer and is additionally introduced into the actual base structure of the layer structure of the laser diode in order to specify the stripe width of the diode laser. This may for example be a p-n tunnel junction according to the invention, an n-current shield, or a corresponding deep implantation area. The p-side total thickness dₜₒₜ including the p-n tunnel junction and the p-side n-contact layer is preferably greater than 2 μm. The total thickness d_{WL} of the waveguide layers is preferably greater than 1 μm. The thickness of the p-side waveguide layer d_{p-WL} is preferably less than 350 nm. A stripe width is preferably greater than or equal to 50 μm. The resonator length L is preferably greater than or equal to 3 mm.

Further preferred configurations of the invention are clear from the features set out in the respective dependent claims.

The various embodiments of the invention set out in this application can advantageously be combined with one another, unless otherwise stated in specific instances.

### BRIEF DESCRIPTION OF THE DRAWINGS

The invention is described below with reference to exemplary embodiments and on the basis of the associated drawings, in which:

FIG. 1 is an exemplary schematic view of a first embodiment of a laser diode according to the invention,

FIG. 2 is an exemplary schematic view of a second embodiment of a laser diode according to the invention,

FIG. 3 is an exemplary schematic view of a third embodiment of a laser diode according to the invention,

FIG. 4 is an exemplary schematic view of a fourth embodiment of a laser diode according to the invention,

FIG. 5 is an exemplary schematic view of a fifth embodiment of a laser diode according to the invention, and

FIG. 6 is an exemplary schematic view of a sixth embodiment of a laser diode according to the invention.

### DETAILED DESCRIPTION OF THE DRAWINGS

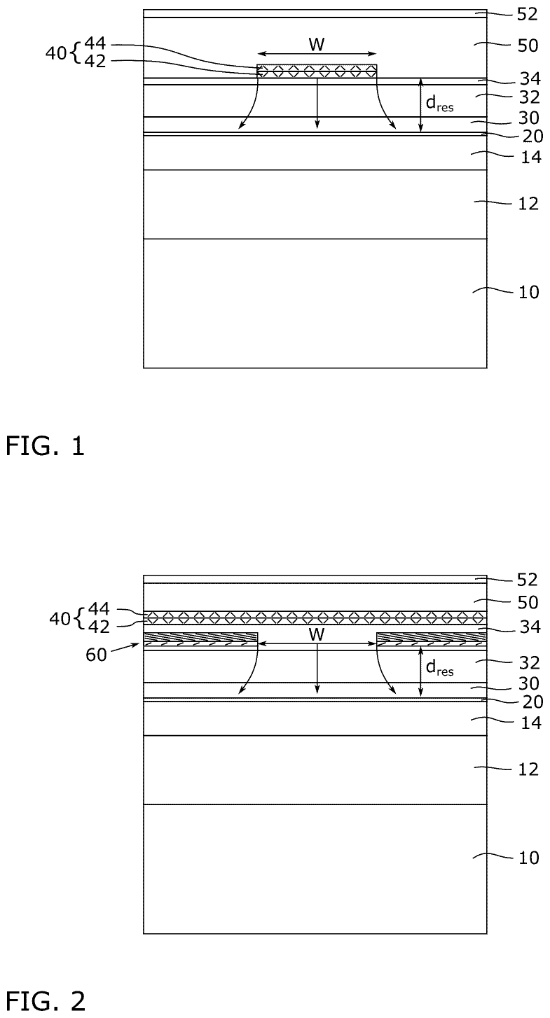

FIG. 1 is an exemplary schematic view of a first embodiment of a laser diode according to the invention. The laser diode shown comprises an active layer 20 formed between an n-doped semiconductor material (n-substrate 10, n-side n-cover layer 12, n-waveguide layer 14) and a p-doped semiconductor material (p-waveguide layer 30, p-cover layer 32, p-sub-contact layer 34), the active layer 20 forming, along a longitudinal axis, an active zone for generating electromagnetic radiation; wherein an n-contact layer 50 is arranged between an overlying p-side metal contact 52 and the p-doped semiconductor material (p-waveguide layer 30, p-cover layer 32, p-sub-contact layer 34), and, in the n-contact layer 50 in the region above the active zone, a p-n tunnel junction 40 being formed which is directly adjacent to the p-doped semiconductor material (p-waveguide layer 30, p-cover layer 32, p-sub-contact layer 34). The p-n tunnel junction 40 shown comprises a p+tunnel layer 42 arranged on the p-doped semiconductor material (p-waveguide layer 30, p-cover layer 32, p-sub-contact layer 34) and an n+tunnel layer 44 arranged thereon. In this embodiment, the p-n tunnel junction 40 is arranged on a p-doped sub-contact layer 34 of the p-doped semiconductor material (p-waveguide layer 30, p-cover layer 32, p-sub-contact layer 34). A stripe width of the diode laser is specified over a lateral width W of the p-n tunnel junction 40. In this embodiment, the residual layer thickness dᵣₑₛ is defined as the minimum distance between the active layer 20 and the p-n tunnel junction 40.

This embodiment of the invention can be provided by a two-stage epitaxy process having an etching step between these two stages. In a first growth step, the structure can be grown as far as the p-n tunnel junction 40. The tunnel junction layers (42, 44) can then be selectively etched away outside the stripe. Following subsequent epitaxial growth of the n-contact layer 50, a p-n junction is produced in the outer regions of the structure in the reverse direction, while the central p-n tunnel junction 40 facilitates the flow of current. This is a known method for current and optical limitation in surface-emitting lasers having vertical resonators (VCSELs).

FIG. 2 is an exemplary schematic view of a second embodiment of a laser diode according to the invention. The basic layer structure corresponds to the arrangement shown in FIG. 1, and therefore the individual reference signs and what they are each assigned to applies accordingly. By contrast with the embodiment shown therein, however, in this case the p-n tunnel junction 40 can be formed as a layer and the stripe width of the diode laser is specified over a lateral width W of an opening in an n-current shield 60 introduced into the p-doped semiconductor material (p-waveguide layer 30, p-cover layer 32, p-sub-contact layer 34). In particular, in the example shown, the n-current shield 60 is arranged within the p-sub-contact layer 34. In this embodiment, the residual layer thickness dᵣₑₛ is defined as the minimum distance between the active layer 20 and the current shield 60.

In this embodiment of the invention, the current confinement can likewise be achieved by a two-step epitaxy process having an etching step between these two steps. In this case, the power cut-off at the component edges is produced independently of the tunnel junction by the so-called (enhanced) self-aligned lateral structure. For this purpose, highly n-doped layers can be integrated in the vicinity of the underside of the p-side contact layer (i.e. the p-sub-contact layer 34), which results in a reverse-biased p-n junction. The first growth step ends after the growth of these layers. They can then be selectively etched away in the center in order to make a corresponding opening for the flow of current. The rest of the p-sub-contact layer 34 as well as the p-n tunnel junction 40 and the n-contact layer 50 can then be grown over the structured n-current shield 60.

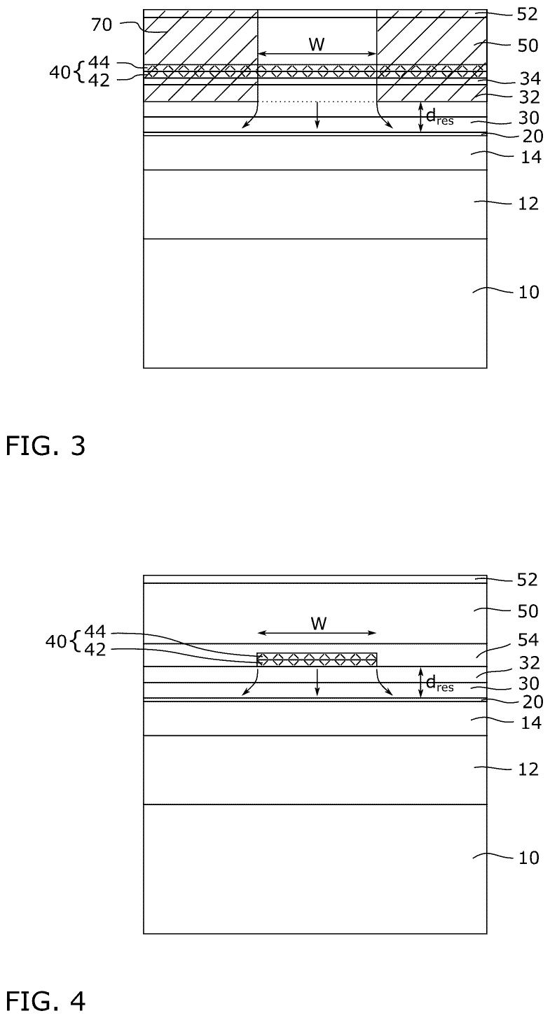

FIG. 3 is an exemplary schematic view of a third embodiment of a laser diode according to the invention. The basic layer structure corresponds to the arrangement shown in FIG. 2, and therefore the individual reference signs and what they are each assigned to applies accordingly. The p-n tunnel junction 40 is likewise formed as a layer here. By contrast with the embodiment shown therein, a stripe width of the diode laser is specified over a lateral width W of a region between two adjacent deep implantation areas 70. In particular, in the example shown, the two marginal deep implantation areas 70 reach from the metal contact 52 into the p-cover layer 32. Since an opening for the flow of current can likewise be made by the deep implantation areas 70, the additional integration of an n-current shield 60 is not required. In this embodiment, the residual layer thickness dᵣₑₛ is defined as the minimum distance between the active layer 20 and the underside of the deep implantation areas 70.

By contrast with the above-described exemplary embodiments, this embodiment can be produced by single-stage epitaxial growth, which reduces the complexity and thus costs of the production process. The current limitation is for example carried out by high-energy deep ion implantation at the edges of the component. This can prevent the flow of current by increasing the intermediate resistance and introducing point defects, at which carriers rapidly recombine. Deep implantation through the active zone effectively prevents current spreading and LCA, as a result of which the beam quality could be considerably improved, but the power and efficiency are significantly impaired. Therefore, an implantation profile that is dimensioned such that it ends above the active zone (e.g. within the p-cover layer) with regard to the total power is preferred.

FIG. 4 is an exemplary schematic view of a fourth embodiment of a laser diode according to the invention. The laser diode shown comprises an active layer 20 formed between an n-doped semiconductor material (n-substrate 10, n-side n-cover layer 12, n-waveguide layer 14) and a p-doped semiconductor material (p-waveguide layer 30, p-cover layer 32), the active layer 20 forming, along a longitudinal axis, an active zone for generating electromagnetic radiation; wherein an n-contact layer 50 and a p-side n-cover layer 54 are arranged between an overlying p-side metal contact 52 and the p-doped semiconductor material (p-waveguide layer 30, p-cover layer 32), and, in the p-side n-contact layer 54 in the region above the active zone, a p-n tunnel junction 40 being formed which is directly adjacent to the p-doped semiconductor material (p-waveguide layer 30, p-cover layer 32). The p-n tunnel junction 40 shown comprises a p⁺ tunnel layer 42 arranged on the p-doped semiconductor material (p-waveguide layer 30, p-cover layer 32) and an n⁺ tunnel layer 44 arranged thereon. In this embodiment, the p-n tunnel junction 40 is arranged on a p-doped cover layer 32 of the p-doped semiconductor material (p-waveguide layer 30, p-cover layer 32). In addition, an n-doped cover layer 54 is arranged on the p-n tunnel junction 40. A stripe width of the diode laser is specified over a lateral width W of the p-n tunnel junction 40. In this embodiment, the residual layer thickness dᵣₑₛ is defined as the minimum distance between the active layer 20 and the p-n tunnel junction 40.

The substantial difference from the embodiment shown in FIG. 1 is therefore that the p-n tunnel junction 40 is arranged on the p-doped cover layer 32 and thus closer to the active zone. The integration of an additional p-sub-contact layer 34 can be omitted. By bringing the p-n tunnel junction 40 closer to the active zone, although the production is more technologically complex (in particular in the variants having two-step epitaxial growth), it can achieve considerable power advantages.

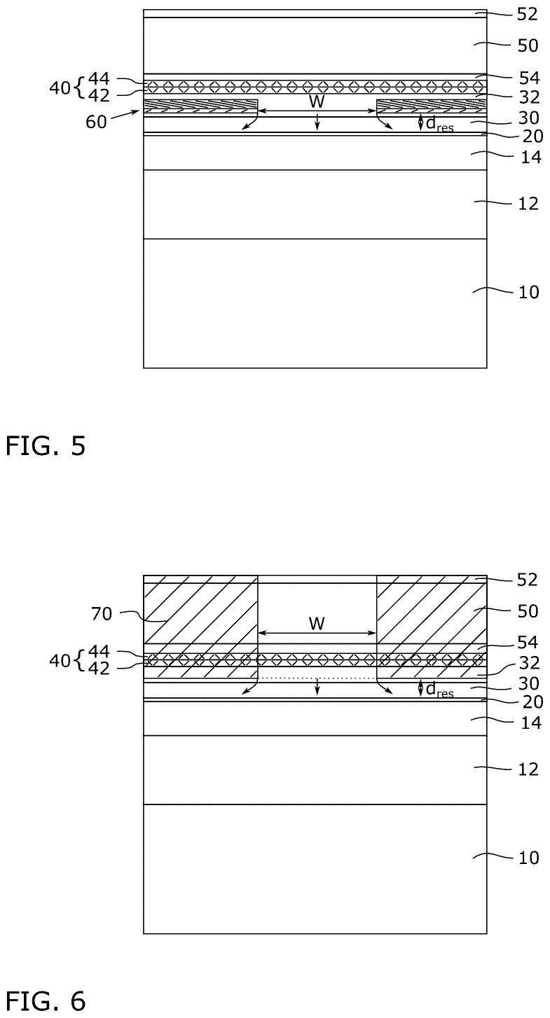

FIG. 5 is an exemplary schematic view of a fifth embodiment of a laser diode according to the invention. The basic layer structure corresponds to the arrangement shown in FIG. 4, and therefore the individual reference signs and what they are each assigned to applies accordingly. The actual operating principle and a possible production method can be seen in FIG. 2, however. This embodiment differs from the embodiment shown in FIG. 2 merely on account of the position of the tunnel junction 40 and the lack of a p-sub-contact layer 34.

FIG. 6 is an exemplary schematic view of a sixth embodiment of a laser diode according to the invention. The basic layer structure corresponds to the arrangement shown in FIG. 5, and therefore the individual reference signs and what they are each assigned to applies accordingly. The actual operating principle and a possible production method can be seen in FIG. 3, however. This embodiment likewise differs from the embodiment shown in FIG. 3 merely on account of the position of the tunnel junction 40 and the lack of a p-sub-contact layer 34.

### LIST OF REFERENCE SIGNS

10 n-substrate (e.g. GaAs)
12 n-cover layer (n-side, e.g. AlGaAs)
14 n-waveguide layer (e.g. AlGaAs)
20 active layer (comprises active zone)
30 p-waveguide layer (e.g. AlGaAs)
32 p-cover layer (e.g. AlGaAs)
34 p-sub-contact layer (e.g. GaAs)
40 p-n tunnel junction
42 p⁺ tunnel layer (e.g. p⁺ GaAs)
44 n⁺ tunnel layer (e.g. n⁺ GaAs)
50 n-(sub-)contact layer (p-side, e.g. GaAs)
52 metal contact (p-side)
54 n-cover layer (p-side, e.g. AlGaAs)
60 n-current shield
70 deep implantation area
W lateral width
dᵣₑₛ residual layer thickness

1. A laser diode, comprising:
an active layer formed between an n-doped semiconductor material and a p-doped semiconductor material, the active layer forming, along a longitudinal axis, an active zone for generating electromagnetic radiation;
wherein at least one n-doped intermediate layer is arranged between an overlying p-side metal contact and the p-doped semiconductor material, and, in the at least one n-doped intermediate layer in the region above the active zone, a p-n tunnel junction being formed which is directly adjacent to the p-doped semiconductor material.

2. The laser diode according to claim 1, wherein the p-n tunnel junction comprises a p⁺ tunnel layer arranged on the p-doped semiconductor material and an n⁺ tunnel layer arranged thereon.

3. The laser diode according to claim 1, wherein the p-n tunnel junction is arranged on a p-doped sub-contact layer of the p-doped semiconductor material.

4. The laser diode according to claim 1, wherein the p-n tunnel junction is arranged on a p-doped cover layer of the p-doped semiconductor material.

5. The laser diode according to claim 1, wherein an n-doped cover layer is arranged on the p-n tunnel junction.

6. The laser diode according to claim 1, wherein a stripe width of the diode laser is specified over a lateral width W of the p-n tunnel junction.

7. The laser diode according to claim 1, wherein the p-n tunnel junction is formed as a layer and a stripe width of the diode laser is specified over a lateral width W of an opening in an n-current shield introduced into the p-doped semiconductor material.

8. The laser diode according to claim 1, wherein the p-n tunnel junction is formed as a layer and a stripe width of the diode laser is specified over a lateral width W of a region between two adjacent deep implantation areas.

9. The laser diode according to claim 1, wherein the semiconductor material is based on GaAs.

10. The laser diode according to claim 1, wherein the minimum distance between the active layer and the p-n tunnel junction is less than 1.3 μm.
